(19) United States
(12) Patent Application Publication
(10) Pub. No.: US 2021/0336100 A1
(43) Pub. Date: Oct. 28, 2021

(54) DISPLAY DEVICE AND MANUFACTURING METHOD OF DISPLAY DEVICE

(71) Applicant: SHENZHEN CHINA STAR OPTOELECTRONICS SEMICONDUCTOR DISPLAY TECHNOLOGY CO., LTD., Shenzhen (CN)

(72) Inventor: Zhiping HU, Shenzhen (CN)

(73) Assignee: SHENZHEN CHINA STAR OPTOELECTRONICS SEMICONDUCTOR DISPLAY TECHNOLOGY CO., LTD., Shenzhen (CN)

(21) Appl. No.: 16/622,943

(22) PCT Filed: Nov. 21, 2019
(86) PCT No.: PCT/CN2019/120029

§ 371 Date: Dec. 16, 2019

(30) Foreign Application Priority Data
Nov. 6, 2019 (CN) 201911077987.6

(51) Int. Cl. H01L 33/50; H01L 25/075; H01L 33/20

(52) U.S. Cl. CPC H01L 33/505; B82Y 20/00; H01L 33/20; H01L 25/0753

(57) ABSTRACT

A display device and a manufacturing method of the display device are provided. The display device includes an array substrate and micro light emitting diode devices. A plurality of micro-cavity structures are disposed on surfaces of the micro light emitting diode devices. Through filling the micro-cavity structures by quantum dot film layers disposed on the micro light emitting diode devices, energy transfer effect between the micro light emitting diode devices and the quantum dots is enhanced, thereby reducing light loss in a photoluminescence process and improving a light utilization rate.

### CROSS REFERENCE TO RELATED APPLICATIONS

This is a U.S. National Phase Application under 35 U.S.C. § 371 of International Patent Application No. PCT/CN2019/120029, filed Nov. 21, 2019, and claims the priority of Chinese Patent Application No. CN201911077987.6 filed on Nov. 6, 2019; the title of the invention is “DISPLAY DEVICE AND MANUFACTURING METHOD OF DISPLAY DEVICE”, and all of which are incorporated by reference herein.

### FIELD OF INVENTION

The present disclosure relates to the field of display technology, and particularly relates to a display device and a manufacturing method of the display device.

### BACKGROUND OF INVENTION

Currently, the development trend of the display technology includes large dimensions, ultra thinness, high resolution, narrow bezels, flexibility, etc. With increasing requirements of display screens, a plurality of new style display technology have come into being, and particularly, organic light emitting diodes (OLEDs), micro light emitting diodes (micro LEDs), and quantum dot technology have obvious advantage on aspect of low power consumption, which is a great development trend of the display technology. However, when display screens of the OLEDs are used, screen burn phenomena easily occur. Comparing micro LEDs to the OLEDs, the micro LEDs use inorganic semiconductor as luminescent material, and stability of the material is better, and service life of devices is longer. In the meantime, they can be thinner and more power saving, while brightness, response time of screens, resolutions, and display effect are better than the OLEDs.

Being as a new technology, technology difficulty and cost of the micro LEDs are too high, and particularly is the mass transferring technology required for transferring LED chips. There are two solutions to realize the micro LEDs to be full color, one of which is to transfer a mass of micro LEDs in three colors of red, blue, and green to corresponding positions, and another one only transfers blue light LEDs, and red pixels and green pixels are used quantum dots and collocated with blue light LEDs. The latter greatly reduces technology difficulty and solves disadvantage of poor service life of red micro LEDs, moreover, using quantum dots to act as light transforming material, having advantages of simple manufacturing processes, spectrum being tunable, and narrow light peaks, which can extend color gamut of the micro LEDs. However, blue light LEDs excite the quantum dot material, therefore, during a process of energy transferring, it is inevitable that a lot of power might loss, for example, loss of waveguide effect from LEDs itself, light scattering effect from quantum dots, etc., and self-absorption phenomena from quantum dot material itself, which makes light lose too much during a photoluminescence process, causing a light utilization rate to be low.

In summary, the current micro LED display devices have the problem of losing too much light in the photoluminescence process that causes a light utilization rate to be low. Therefore, it is necessary to provide a display device and a manufacturing method of the display device to improve this defect.

### SUMMARY OF INVENTION

Embodiments the present disclosure provide a display device and a manufacturing method of the display device for solving the problem of losing too much light in the photoluminescence process that causes a light utilization rate to be low.

An embodiment of the present disclosure provides a display device, including:

An array substrate.

A plurality of micro light emitting diode devices are arranged on the array substrate in an array manner. A plurality of micro-cavity structures caving toward an inner side of the micro light emitting diode devices are disposed on surfaces of sides of the micro light emitting diode devices away from the array substrate.

A plurality of quantum dot film layers are disposed on the sides of the micro light emitting diode devices away from the array substrate and fill the micro-cavity structures.

According to an embodiment of the present disclosure, shapes of bottom surfaces of the micro-cavity structures include rectangular shapes, circular shapes, or ellipses, and the plurality of the micro-cavity structures are successively arranged on the surfaces of the sides of the micro light emitting diode devices away from the array substrate.

According to an embodiment of the present disclosure, the micro light emitting diode devices include a blue micro light emitting diode device, and the quantum dot film layers include a red quantum dot film layer, and a green quantum dot film layer.

According to an embodiment of the present disclosure, material of the quantum dot film layers includes photocuring material containing quantum dots.

According to an embodiment of the present disclosure, first walls are disposed between the adjacent micro light emitting diode devices, and the first walls separate the adjacent micro light emitting diode devices and the adjacent quantum dot film layers from each other.

According to an embodiment of the present disclosure, heights of the first walls in a direction vertical to the array substrate are greater than heights of the micro light emitting diode devices.

According to an embodiment of the present disclosure, the display device includes a glass substrate disposed opposite to the array substrate, a color filter layer is disposed on a side of the glass substrate close to the array substrate, and the color filter layer includes a plurality of color resists corresponding to the micro light emitting diode devices and the quantum dot film layers one by one.

According to an embodiment of the present disclosure, second walls are disposed on a side of the glass substrate close to the array substrate, and the second walls are disposed between the adjacent color resists.

An embodiment of the present disclosure provides a display device, including:

An array substrate.

A plurality of blue micro light emitting diode devices are arranged on the array substrate in an array manner. A plurality of micro-cavity structures caving toward an inner side of the blue micro light emitting diode devices and being successively arranged are disposed on surfaces of sides of the blue micro light emitting diode devices away from the array substrate.

A red quantum dot film layer and a green quantum dot film layer are disposed on the sides of the blue micro light emitting diode devices away from the array substrate and fill the micro-cavity structures.

According to an embodiment of the present disclosure, shapes of bottom surfaces of the micro-cavity structures include rectangular shapes, circular shapes, or ellipses, and the plurality of the micro-cavity structures are successively arranged on the surfaces of the sides of the blue micro light emitting diode devices away from the array substrate.

According to an embodiment of the present disclosure, material of the red quantum dot film layer and the green quantum dot film layer includes photocuring material containing quantum dots.

According to an embodiment of the present disclosure, first walls are disposed between the adjacent blue micro light emitting diode devices, and the first walls separate the adjacent blue micro light emitting diode devices and the red quantum dot film layer and the green quantum dot film layer adjacent to each other.

According to an embodiment of the present disclosure, heights of the first walls on a direction vertical to the array substrate are greater than heights of the blue micro light emitting diode devices.

According to an embodiment of the present disclosure, the display device includes a glass substrate disposed opposite to the array substrate, a color filter layer is disposed on a side of the second substrate close to the array substrate, the color filter layer includes a plurality of color resists corresponding to the red quantum dot film layer and the green quantum dot film layer one by one.

According to an embodiment of the present disclosure, second walls are disposed on a side of the glass substrate close to the array substrate, and the second walls are disposed between the adjacent color resists.

An embodiment of the present disclosure provides a manufacturing method of a display device, including:

Providing a light emitting diode substrate which includes a substrate and a light emitting diode film layer located on the substrate, and coating imprinting glue on a surface of the light emitting diode film layer.

Imprinting an imprinting mold into the imprinting glue, after curing by ultraviolet, taking out the imprinting mold to form an imprinting layer.

Etching to remove the imprinting layer, and forming imprinting glue patterns on the surface of the light emitting diode film layer.

Etching a surface of a side of the light emitting diode film layer away from the substrate to form a plurality of micro-cavity structures arranged at intervals and caving toward an inner side of the light emitting diode film layer.

Removing the imprinting glue patterns on the surface of the light emitting diode film layer.

Cutting the light emitting diode substrate to form a plurality of micro light emitting diode devices.

According to an embodiment of the present disclosure, the manufacturing method further includes:

Providing a base substrate, and forming a thin film transistor driving array on the base substrate.

Coating a black photoresist on the base substrate to cover a mask plate, after curing by ultraviolet, removing the remaining photoresist to form patterned first walls.

Transferring the micro light emitting diode devices onto the base substrate.

The beneficial effect of the present disclosure: by disposing the plurality of micro-cavity structures caving toward an inner side of the light emitting diode film layer on the surface of the side of the micro light emitting diode devices away from the array substrate, and filling the micro-cavity structures by the quantum dot film layer disposed on the micro light emitting diode devices, embodiments of the present disclosure makes the quantum dots be distributed in each micro-cavity structure on surfaces of micro light emitting diode devices to prevent from aggregation of the quantum dot, and meanwhile restricts the quantum dots in the inner side of the micro light emitting diode devices, and the plurality of micro-cavity structures containing the quantum dots can enhance energy transfer effect between the micro light emitting diode devices and the quantum dots, thereby reducing light loss in a photoluminescence process and improving a light utilization rate.

### DESCRIPTION OF DRAWINGS

To more clearly illustrate embodiments or the technical solutions of the present disclosure, the accompanying figures of the present disclosure required for illustrating embodiments or the technical solutions of the present disclosure will be described in brief. Obviously, the accompanying figures described below are only part of the embodiments of the present disclosure, from which those skilled in the art can derive further figures without making any inventive efforts.

FIG. 1 is a schematic diagram of a sectional structure of a display device provided by a first embodiment of the present disclosure.

FIG. 2 is a schematic diagram of a sectional structure of a display device provided by a second embodiment of the present disclosure.

FIG. 3A to FIG. 3E are structural schematic diagrams of a light emitting diode substrate provided by a third embodiment of the present disclosure.

FIG. 3F is a structural schematic diagram of micro light emitting diode devices provide by the third embodiment of the present disclosure.

FIG. 4A to FIG. 4D are structural schematic diagrams of the array substrate provided by the third embodiment of the present disclosure.

### DETAILED DESCRIPTION OF PREFERRED EMBODIMENTS

The descriptions of embodiments below refer to accompanying drawings in order to illustrate certain embodiments which the present disclosure can implement. The directional terms of which the present disclosure mentions, for example, “top”, “bottom”, “upper”, “lower”, “front”, “rear”, “left”, “right”, “inside”, “outside”, “side”, etc., only refer to directions of the accompanying figures. Therefore, the used directional terms are for illustrating and understanding the present disclosure, but not for limiting the present disclosure. In the figures, units with similar structures are indicated by the same reference numerals.

The present disclosure will be further described in detail below in combination with the drawings and specific embodiments.

### The First Embodiment

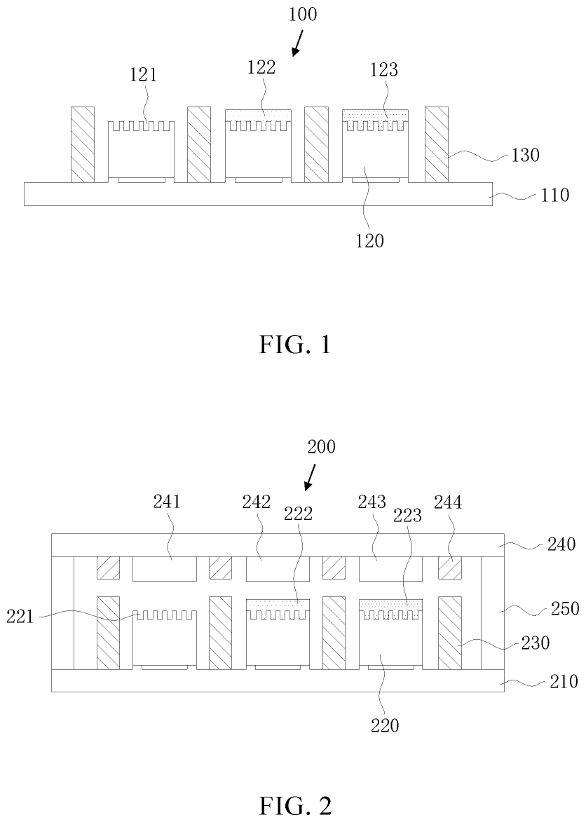

The embodiment of the present disclosure provides a display device, and it will be described in detail in combined with FIG. 1 as the following.

Illustrated in FIG. 1 is a schematic diagram of a sectional structure of a display device 100 provided by an embodiment of the present disclosure. The display device 100 includes an array substrate 110, micro light emitting diode devices 120, and quantum dot film layers. A pixel driving circuit (not shown in the figure) is disposed on the array substrate 110. The micro light emitting diode devices 120 are arranged on the array substrate 110 in an array manner. A plurality of micro-cavity structures 121 caving toward an inner side of the micro light emitting diode devices 120 are disposed on surfaces of sides of the micro light emitting diode devices 120 away from the array substrate 110.

Preferably, shapes of bottom surfaces of the micro-cavity structures 121 include rectangular shapes, circular shapes, or ellipses.

In some embodiment, the shapes of the bottom surfaces of the micro-cavity structures 121 may be adjusted to other shapes according to actual requirements, and are not limited herein.

The plurality of the micro-cavity structures 121 are successively arranged on the surfaces of the sides of the micro light emitting diode devices 120 away from the array substrate 110.

As illustrated in FIG. 1, the quantum dot film layers are disposed on the sides of the micro light emitting diode devices 120 away from the array substrate 110 and fill the micro-cavity structures 121.

Using the micro-cavity structures 121 separated from each other to distribute quantum dots in the quantum dot film layers to each micro-cavity structures on the surfaces of the micro light emitting diode devices, which prevents from aggregation of the quantum dot, and meanwhile restricts the quantum dots in the inner side of the micro light emitting diode devices, and the plurality of micro-cavity structures containing the quantum dots can enhance energy transfer effect between the micro light emitting diode devices and the quantum dots, thereby reducing light loss in a photoluminescence process and improving a light utilization rate.

Specifically, the micro light emitting diode devices 120 are blue micro light emitting diode devices, and the quantum dot film layers include a red quantum dot film layer 122, and a green quantum dot film layer 123, and the quantum dot film layers do not cover all of the micro light emitting diode devices 120. Furthermore, the blue micro light emitting diode device 120 itself emits blue light. If the blue micro light emitting diode device 120 is disposed in a blue subpixel region of the array substrate 110, there will not need to dispose any quantum dot film layer thereon. The red quantum dot film layer 122 and the green quantum dot film layer 123 have transformation effect on blue light emitted from the micro light emitting diode devices. If disposing on a red subpixel region, the red quantum dot film layer 122 is covered, and blue light emitted from the micro light emitting diode device 120 passes through the red quantum dot film layer 122 and is transformed to red light. If disposing on a green subpixel region, the green quantum dot film layer 123 is covered, and blue light emitted from the micro light emitting diode device 120 passes through the green quantum dot film layer 123 and is transformed to green light. Therefore, transformation of a red pixel, a green pixel, and a blue pixel is formed on the array substrate 110, and full color display of the display device 100 is realized.

Preferably, material of the quantum dot film layers includes photocuring material containing quantum dots.

As illustrated in FIG. 1, first walls 130 are disposed between the adjacent micro light emitting diode devices 120, and the first walls 130 encircle periphery of each micro light emitting diode devices 120 to separate the adjacent micro light emitting diode devices 120 and simultaneously separate the adjacent red quantum dot film layer 122 and the green quantum dot film layer 123 above the micro light emitting diode devices 120, which prevents light emitted from the micro light emitting diode devices 120 perform crosstalk on the adjacent micro light emitting diode devices 120, causing poor display of the display device 100.

Preferably, material of the first walls 130 is as same as material of black photoresist in the art. Meanwhile, for weakening crosstalk of light, shielding effect of the first walls 130 is improved, and heights of the first walls 130 in a direction vertical to the array substrate 110 are greater than heights of the micro light emitting diode devices 120.

In an embodiment of the present disclosure, an encapsulation layer is disposed on the array substrate 110 (not shown in the figure). The encapsulation layer covers the micro light emitting diode devices 120 and the first walls 130 and extends to an edge of the array substrate 110 to prevent display devices such as the pixel driving circuit, the micro light emitting diode devices 120, etc. on the array substrate from suffering erosion of water vapor and oxygen.

The beneficial effect of the embodiments of the present disclosure: by disposing the plurality of micro-cavity structures caving toward an inner side of the light emitting diode film layer on the surface of the side of the micro light emitting diode devices away from the array substrate, and filling the micro-cavity structures by the quantum dot film layer disposed on the micro light emitting diode devices, embodiments of the present disclosure makes the quantum dots be distributed in each micro-cavity structure on surfaces of micro light emitting diode devices to prevent from aggregation of the quantum dot, and meanwhile restricts the quantum dots in the inner side of the micro light emitting diode devices, and the plurality of micro-cavity structures containing the quantum dots can enhance energy transfer effect between the micro light emitting diode devices and the quantum dots, thereby reducing light loss in a photoluminescence process and improving a light utilization rate.

### The Second Embodiment

The embodiment of the present disclosure provides a display device 200, and it will be described in detail in combined with FIG. 2 as the following.

Illustrated in FIG. 2 is a schematic diagram of a sectional structure of a display device 200 provided by the embodiment of the present disclosure. The display device 200 includes an array substrate 210, micro light emitting diode devices 220, and quantum dot film layers. A pixel driving circuit (not shown in the figure) is disposed on the array substrate 210. The micro light emitting diode devices 220 are arranged on the array substrate 210 in an array manner. A plurality of micro-cavity structures 221 caving toward an inner side of the micro light emitting diode devices 220 are disposed on surfaces of sides of the micro light emitting diode devices 220 away from the array substrate 210.

Preferably, shapes of bottom surfaces of the micro-cavity structures 221 include rectangular shapes, circular shapes, or ellipses. In some embodiment, the shapes of the bottom surfaces of the micro-cavity structures 221 may be adjusted to other shapes according to actual requirements, and are not limited herein. The plurality of the micro-cavity structures 221 are successively arranged on the surfaces of the sides of the micro light emitting diode devices 220 away from the array substrate 210.

As illustrated in FIG. 2, the quantum dot film layers are disposed on the sides of the micro light emitting diode devices 220 away from the array substrate 210 and fill the micro-cavity structures 221. Using the micro-cavity structures 221 separated from each other to distribute quantum dots in the quantum dot film layers to each micro-cavity structures on the surfaces of the micro light emitting diode devices to prevent from aggregation of the quantum dot, and meanwhile restricts the quantum dots in the inner side of the micro light emitting diode devices, and the plurality of micro-cavity structures containing the quantum dots can enhance energy transfer effect between the micro light emitting diode devices and the quantum dots, thereby reducing light loss in a photoluminescence process and improving a light utilization rate.

Specifically, the micro light emitting diode devices 220 are blue micro light emitting diode devices, and the quantum dot film layers include a red quantum dot film layer 222, and a green quantum dot film layer 223, and the quantum dot film layers do not cover all of the micro light emitting diode devices 220. Furthermore, the blue micro light emitting diode device 220 itself emits blue light. If the blue micro light emitting diode device 210 is disposed in a blue subpixel region of the array substrate 210, there will not need to dispose any quantum dot film layer thereon. The red quantum dot film layer 222 and the green quantum dot film layer 223 have transformation effect to blue light emitted from the micro light emitting diode devices. If disposing on a red subpixel region, the red quantum dot film layer 222 is covered, and blue light emitted from the micro light emitting diode device 220 passes through the red quantum dot film layer 222 and is transformed to red light. If disposing on a green subpixel region, the green quantum dot film layer 223 is covered, and blue light emitted from the micro light emitting diode device 220 passes through the green quantum dot film layer 223 and is transformed to green light. Therefore, transformation of a red pixel, a green pixel, and a blue pixel is formed on the array substrate 210, and full color display of the display device 200 is realized.

Preferably, material of the quantum dot film layers comprises photocuring material containing quantum dots.

As illustrated in FIG. 2, first walls 230 are disposed between the adjacent micro light emitting diode devices 220, and the first walls 230 encircle periphery of each micro light emitting diode devices 220 to separate the adjacent micro light emitting diode devices 220 and simultaneously separate the adjacent red quantum dot film layer 222 and the green quantum dot film layer 223 above the micro light emitting diode devices 220, which prevents light emitted from the micro light emitting diode devices 220 perform crosstalk on the adjacent micro light emitting diode devices 220, causing poor display of the display device 200.

Preferably, material of the first walls 230 is as same as material of black photoresist in the art. Meanwhile, for weakening crosstalk of light, shielding effect of the first walls 230 is improved, and heights of the first walls 230 in a direction vertical to the array substrate 210 are greater than heights of the micro light emitting diode devices 220.

As illustrated in FIG. 2, in an embodiment of the present disclosure, the display device 200 further includes a glass substrate 240 disposed opposite to the array substrate 210. A color filter layer is disposed on a side of the glass substrate 240 close to the array substrate 210, and the color filter layer includes a plurality of color resists corresponding to the quantum dot film layers and the micro light emitting diode devices 220 one by one. The array substrate 210 and the glass substrate 240 is sealed and bonded therebetween by encapsulation sealant 250.

Specifically, the color resists include a blue color resist 241, a red color resist 242, and a green color resist 243. The blue color resist 241 corresponds to the blue micro light emitting diode device not covered by the quantum dot film layer, the red color resist 242 corresponds to the red quantum dot film layer 222, and the green color resist 243 corresponds to the green quantum dot film layer 223. By disposing color filter layer on the opposite side of the array substrate to transform the blue light not absorbed by the quantum dot film layer, display effect of the display device 200 is improved.

Preferably, second walls 244 are disposed on a side of the glass substrate 240 close to the array substrate 210, and the second walls 244 are disposed between the adjacent color resists and encircle periphery of each color resist to separate the color resists from each other, thereby preventing light emitted from the micro light emitting diode devices 220 perform crosstalk on the adjacent color resists, affecting display effect of the display device 200.

The beneficial effect of the embodiments of the present disclosure: by disposing the plurality of micro-cavity structures caving toward an inner side of the light emitting diode film layer on the surface of the side of the micro light emitting diode devices away from the array substrate, and filling the micro-cavity structures by the quantum dot film layer disposed on the micro light emitting diode devices, embodiments of the present disclosure makes the quantum dots be distributed in each micro-cavity structure on surfaces of micro light emitting diode devices to prevent from aggregation of the quantum dot, and meanwhile restricts the quantum dots in the inner side of the micro light emitting diode devices, and the plurality of micro-cavity structures containing the quantum dots can enhance energy transfer effect between the micro light emitting diode devices and the quantum dots, thereby reducing light loss in a photoluminescence process and improving a light utilization rate.

### The Third Embodiment

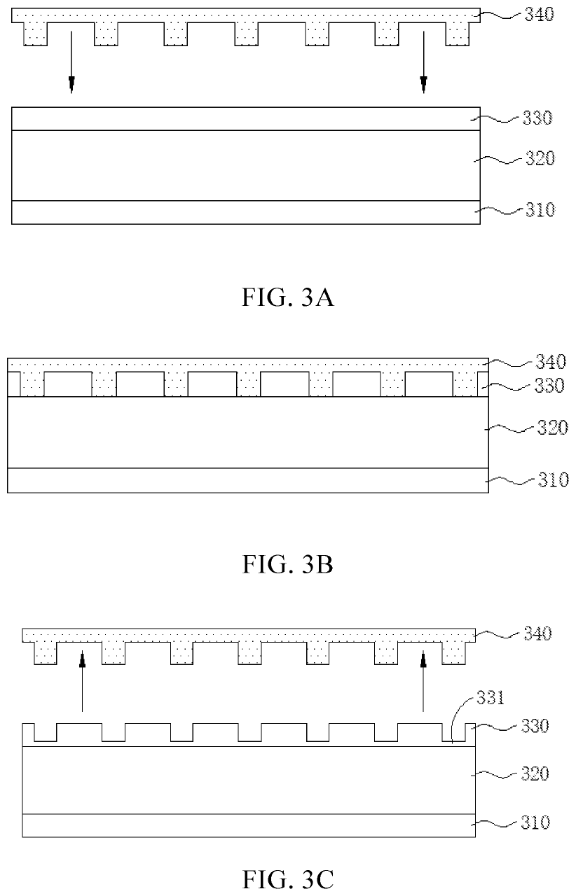

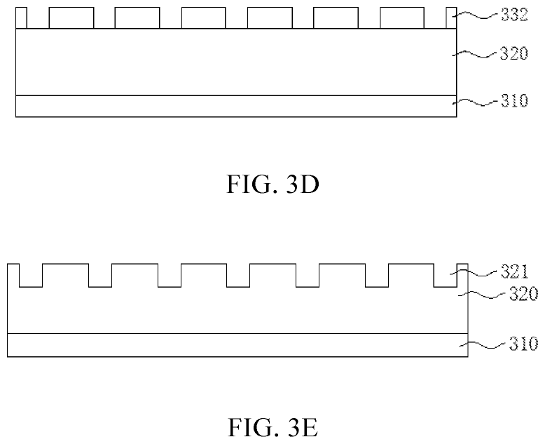

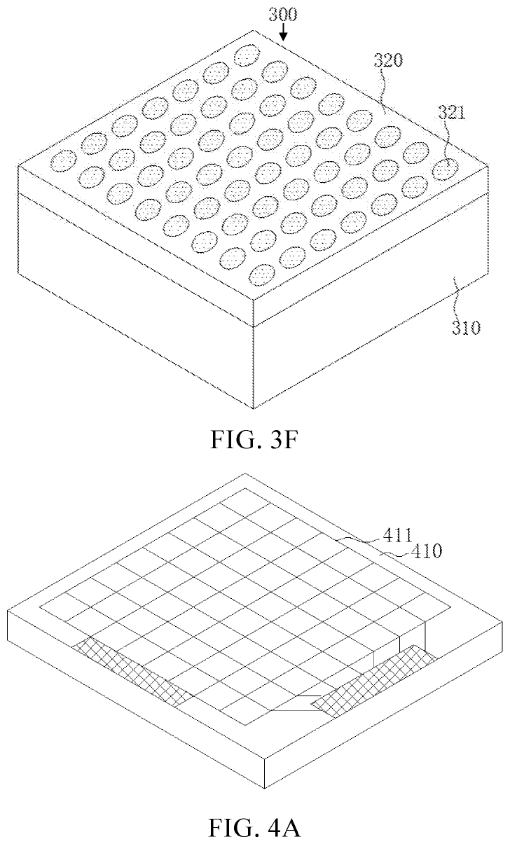

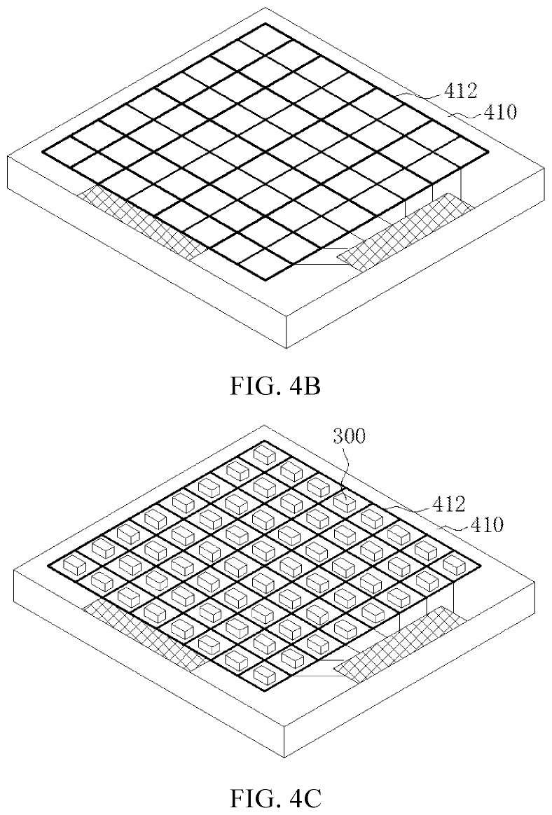

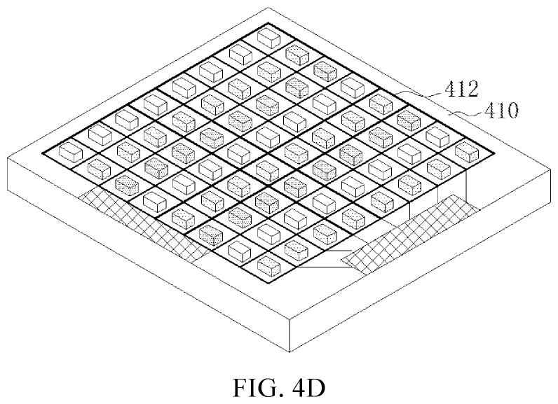

The embodiment of the present disclosure provides a manufacturing method of a display device, and it will be described in detail in combined with FIG. 3A to FIG. 4D as the following.

As illustrated in FIG. 3A to FIG. 3F, FIG. 3A to FIG. 3E are schematic diagrams of sectional structures of a light emitting diode substrate provided by the embodiment of the present disclosure, and FIG. 3F is a structural schematic diagram of micro light emitting diode devices. The manufacturing method includes:

Step S10: as illustrate in FIG. 3A, providing a light emitting diode substrate which includes a substrate 310 and a light emitting diode film layer 320 located on the substrate 310, and coating imprinting glue 330 on a surface of the light emitting diode film layer 320. Furthermore, the imprinting glue 330 is nano-imprinting glue.

Step S20: as illustrated in FIG. 3A and FIG. 3B, imprinting an imprinting mold 340 into the imprinting glue 330 along a direction of the arrow, and after curing by ultraviolet, taking out the imprinting mold 340. The section imprinted by the imprinting mold 340 forms an imprinting layer 331 illustrated in FIG. 3C. Furthermore, the imprinting mold 340 is a nano-imprinting mold.

Step S30: etching to remove the imprinting layer 331, and forming imprinting glue patterns 332 on the surface of the light emitting diode film layer 320 as illustrated in FIG. 3D.

Step S40: etching a surface of a side of the light emitting diode film layer 320 away from the substrate 310 to form a plurality of micro-cavity 321 structures arranged at intervals and caving toward an inner side of the light emitting diode film layer 320 as illustrated in FIG. 3E. The imprinting glue patterns 332 can act as a mask plate of this step, and the method of etching the light emitting diode film layer 320 includes an inductively coupled plasma method or a reaction ion etching method.

Step S50: removing the imprinting glue patterns 332 on the surface of the light emitting diode film layer 320. Furthermore, technical processes of removing the imprinting glue patterns 332 include technical processes of glue removing, corrosion, cleaning, drying, etc.

Step S60: cutting the light emitting diode substrate to form a plurality of micro light emitting diode devices 300. Furthermore, the method of cutting the light emitting diode substrate includes a laser cutting method. As illustrated in FIG. 3F, the plurality of the micro-cavity structures 321 are successively arranged on the surfaces of the sides of the micro light emitting diode devices 320.

In the embodiment of the present disclosure, illustrated in FIG. 4A to FIG. 4D are structural schematic diagrams of the array substrate provided by an embodiment of the present disclosure. The manufacturing method further includes:

Step S701: as illustrated in FIG. 4A, providing a base substrate 410, and forming a thin film transistor driving array 411 on the base substrate, so that the array substrate is formed.

Step S702: as illustrated in FIG. 4B, coating a black photoresist on the base substrate 410 to cover a mask plate, after curing by ultraviolet, removing the remaining photoresist by developer to form patterned first walls 412.

Step 703: transferring the micro light emitting diode devices 300 onto the base substrate. As illustrated in FIG. 4C, the first walls 412 are disposed between the adjacent micro light emitting diode devices 300 and encircle periphery of the micro light emitting diode devices 300 to separate the adjacent micro light emitting diode devices 300 from each other.

Step 704: coating quantum dot ink on surfaces of sides of the micro light emitting diode devices 300 away from the base substrate 410.

Step S705: curing the quantum dot ink by ultraviolet to form the quantum dot film layers.

Furthermore, the quantum dot film layers cover the surfaces of the micro light emitting diode devices 300 and fill the micro-cavity structures 321. The plurality of micro-cavity structures 321 distribute quantum dots to each micro-cavity structures on the surfaces of the micro light emitting diode devices 300 to prevent from aggregation of the quantum dot, and meanwhile restricts the quantum dots in the inner side of the micro light emitting diode devices, and the plurality of micro-cavity structures containing the quantum dots can enhance energy transfer effect between the micro light emitting diode devices and the quantum dots, thereby reducing light loss in a photoluminescence process and improving a light utilization rate.

After the steps mentioned above are finished, the full color array substrate as illustrated in FIG. 4D can be completely manufactured. The micro light emitting diode device 300 is a blue micro light emitting diode device, and the quantum dot film layers include a red quantum dot film layer, and a green quantum dot film layer. Transforming light emitted from the blue micro light emitting diode device by the quantum dot film layers, display effect of a red pixel, a green pixel, and a blue pixel can be realized. The arrangement manner of the quantum dot film layers and the arrangement manner of the micro light emitting diode devices 300 are not limited herein, and they can be adjusted according to actual requirements.

In an embodiment of the present disclosure, the follow-up processes further includes performing a thin film encapsulation process on the full color array substrate, and the step is as same as the steps in the prior art, and details are not described herein again.

In an embodiment of the present disclosure, the method of coating the quantum dot ink in the step S704 is an ink printing method.

The beneficial effect of the embodiments of the present disclosure: the embodiments of the present disclosure provide a manufacturing method of a display device, by forming a plurality of micro-cavity structures caving toward an inner side of the light emitting diode film layer on the surface of the micro light emitting diode devices, which makes the quantum dot film layers cover the surfaces of the micro light emitting diode devices and simultaneously fill the micro-cavity structures, and makes the quantum dots be distributed in each micro-cavity structure on surfaces of micro light emitting diode devices to prevent from aggregation of the quantum dots, and meanwhile restricts the quantum dots in the inner side of the micro light emitting diode devices, and the plurality of micro-cavity structures containing the quantum dots can enhance energy transfer effect between the micro light emitting diode devices and the quantum dots, thereby reducing light loss in a photoluminescence process and improving a light utilization rate.

In summary, although the present disclosure has disclosed the preferred embodiments as above, however the above-mentioned preferred embodiments are not to limit to the present disclosure. A person skilled in the art can make any change and modification, therefore the scope of protection of the present disclosure is subject to the scope defined by the claims.

What is claimed is:

1. A display device, comprising:
an array substrate;
a plurality of micro light emitting diode devices arranged on the array substrate in an array manner, wherein a plurality of micro-cavity structures caving toward an inner side of the micro light emitting diode devices are disposed on surfaces of sides of the micro light emitting diode devices away from the array substrate; and
a plurality of quantum dot film layers disposed on the sides of the micro light emitting diode devices away from the array substrate and filling the micro-cavity structures.

2. The display device as claimed in claim 1, wherein shapes of bottom surfaces of the micro-cavity structures comprise rectangular shapes, circular shapes, or ellipses, and the plurality of the micro-cavity structures are successively arranged on the surfaces of the sides of the micro light emitting diode devices away from the array substrate.

3. The display device as claimed in claim 1, wherein the micro light emitting diode devices comprise a blue micro light emitting diode device, and the quantum dot film layers comprise a red quantum dot film layer and a green quantum dot film layer.

4. The display device as claimed in claim 1, wherein a material of the quantum dot film layers comprises photocuring material containing quantum dots.

5. The display device as claimed in claim 1, wherein first walls are disposed between adjacent micro light emitting diode devices, and the first walls separate the adjacent micro light emitting diode devices and adjacent quantum dot film layers from each other.

6. The display device as claimed in claim 5, wherein heights of the first walls in a direction vertical to the array substrate are greater than heights of the micro light emitting diode devices.

7. The display device as claimed in claim 1, wherein the display device comprises a glass substrate disposed opposite to the array substrate, a color filter layer is disposed on a side of the glass substrate close to the array substrate, and the color filter layer comprises a plurality of color resists corresponding to the micro light emitting diode devices and the quantum dot film layers one by one.

8. The display device as claimed in claim 7, wherein second walls are disposed on the side of the glass substrate close to the array substrate, and the second walls are disposed between adjacent color resists.

9. A display device, comprising:
an array substrate;
a plurality of blue micro light emitting diode devices arranged on the array substrate in an array manner, wherein a plurality of micro-cavity structures caving toward an inner side of the blue micro light emitting diode devices are successively arranged and disposed on surfaces of sides of the blue micro light emitting diode devices away from the array substrate; and
a red quantum dot film layer and a green quantum dot film layer disposed on the sides of the blue micro light emitting diode devices away from the array substrate and filling the micro-cavity structures.

10. The display device as claimed in claim 9, wherein shapes of bottom surfaces of the micro-cavity structures comprise rectangular shapes, circular shapes, or ellipses, and the plurality of the micro-cavity structures are successively arranged on the surfaces of the sides of the blue micro light emitting diode devices away from the array substrate.

11. The display device as claimed in claim 9, wherein a material of the red quantum dot film layer and the green quantum dot film layer comprises photocuring material containing quantum dots.

12. The display device as claimed in claim 9, wherein first walls are disposed between adjacent blue micro light emitting diode devices, and the first walls separate the adjacent blue micro light emitting diode devices and the red quantum dot film layer and the green quantum dot film layer adjacent to each other.

13. The display device as claimed in claim 12, wherein heights of the first walls in a direction vertical to the array substrate are greater than heights of the blue micro light emitting diode devices.

14. The display device as claimed in claim 9, wherein the display device comprises a glass substrate disposed opposite to the array substrate, a color filter layer is disposed on a side of the glass substrate close to the array substrate, and the color filter layer comprises a plurality of color resists corresponding to the red quantum dot film layer and the green quantum dot film layer one by one.

15. The display device as claimed in claim 14, wherein second walls are disposed on the side of the glass substrate close to the array substrate, and the second walls are disposed between adjacent color resists.

16. A manufacturing method of a display device, comprising:
providing a light emitting diode substrate which comprises a substrate and a light emitting diode film layer located on the substrate, and coating imprinting glue on a surface of the light emitting diode film layer;
imprinting an imprinting mold into the imprinting glue, and after curing by ultraviolet, taking out the imprinting mold to form an imprinting layer;
etching to remove the imprinting layer, and forming imprinting glue patterns on the surface of the light emitting diode film layer;
etching a surface of a side of the light emitting diode film layer away from the substrate to form a plurality of micro-cavity structures arranged at intervals and caving toward an inner side of the light emitting diode film layer;
removing the imprinting glue patterns on the surface of the light emitting diode film layer; and
cutting the light emitting diode substrate to form a plurality of micro light emitting diode devices.

17. The manufacturing method as claimed in claim 16, wherein the manufacturing method comprises:
providing a base substrate, and forming a thin film transistor driving array on the base substrate;
coating a black photoresist on the base substrate to cover a mask plate, and after curing by ultraviolet, removing the remaining photoresist to form patterned first walls; and
transferring the micro light emitting diode devices onto the base substrate.
